(19) United States
(12) Patent Application Publication
(10) Pub. No.: US 2026/0269090 A1
(43) Pub. Date: Sep. 10, 2026

(54) BURNABLE ABSORBER TRISTRUCTURAL ISOTROPIC PARTICLES AND RELATED METHODS AND FUEL COMPACTS

(71) Applicant: Battelle Energy Alliance, LLC, Idaho Falls, ID (US)

(72) Inventors: Jordan A. Evans, Idaho Falls, ID (US); Kevan D. Weaver, Idaho Falls, ID (US); Jackson R. Harter, Idaho Falls, ID (US)

(21) Appl. No.: 19/480,006

(22) PCT Filed: May 1, 2024
(86) PCT No.: PCT/US2024/027280

§ 371 Date: Oct. 29, 2025

Related U.S. Application Data
(60) Provisional application No. 63/499,640, filed on May 2, 2023.

(51) Int. Cl. G21C 7/04; C23C 16/26; C23C 16/32; C23C 16/442

(52) U.S. Cl. CPC G21C 7/04; C23C 16/26; C23C 16/325; C23C 16/442

(57) ABSTRACT

A burnable absorber tristructural isotropic (TRISO) particle that comprises a kernel that comprises a non-fissile neutron-absorbing material, a porous carbon buffer layer surrounding the kernel, a first pyrolytic carbon layer surrounding the porous carbon buffer layer, a silicon carbide layer surrounding the first pyrolytic carbon layer, and a second pyrolytic carbon layer surrounding the silicon carbide layer. A fuel compact comprising burnable absorber TRISO particles and TRISO fuel particles is also disclosed, as is a method of forming the burnable absorber TRISO particle.

### CROSS-REFERENCE TO RELATED APPLICATIONS

This application is a national phase entry under 35 U.S.C. § 371 of International Patent Application PCT/US2024/027280, filed May 1, 2024, designating the United States of America and published as International Patent Publication WO 2025/188331 A2 on Sep. 12, 2025, which claims the benefit under Article 8 of the Patent Cooperation Treaty of U.S. Patent Application Ser. No. 63/499,640, filed May 2, 2023, the disclosure of each of which is hereby incorporated herein in its entirety by this reference.

### STATEMENT REGARDING FEDERALLY SPONSORED RESEARCH OR DEVELOPMENT

This invention was made with government support under Contract Number DE-AC07-05-ID14517 awarded by the United States Department of Energy. The government has certain rights in the invention.

### TECHNICAL FIELD

Embodiments of the disclosure relate generally to burnable absorbers used in fuel compacts for nuclear reactors. More particularly, embodiments of the disclosure relate to a burnable absorber material in an inner portion of a tristructural isotropic particle and to fuel compacts including the burnable absorber material.

### BACKGROUND

Tristructural isotropic (TRISO) fuel particles, originally developed for use in high-temperature gas-cooled reactors (HTGRs), offer safety and performance characteristics that make them an attractive fuel for other advanced nuclear reactor designs. The TRISO fuel particles contain a fuel kernel, such as uranium oxycarbide, surrounded by a porous graphite buffer layer, an inner pyrolytic carbon layer, a silicon carbide layer, and a dense outer pyrolytic carbon layer. This configuration prevents the leakage of fission products from the TRISO fuel particles and allows them to withstand extreme conditions of radiation damage, high temperature, and high burnup associated with next-generation nuclear reactors.

To offset excess reactivity of fresh fuel and flatten the power profile, burnable absorbers (BAs) are used instead of control rods, which are inserted into a nuclear reactor core. The BA material includes non-fissile nuclei with large neutron-absorption cross sections. The BA material absorbs excess neutrons released by the fission reaction of the nuclear fuel, decreasing the neutron population significantly in the fresh fuel configuration. The BA is formulated to have decreasing impact as it is consumed over the reactor core's operational fuel cycle, allowing reactivity to remain relatively constant despite the gradual depletion of the fuel.

### BRIEF SUMMARY

A burnable absorber tristructural isotropic (TRISO) particle is disclosed and comprises a kernel comprising a non-fissile, neutron-absorbing material, a porous carbon buffer layer surrounding the kernel, a first pyrolytic carbon layer surrounding the porous carbon buffer layer, a silicon carbide layer surrounding the first pyrolytic carbon layer, and a second pyrolytic carbon layer surrounding the silicon carbide layer.

A fuel compact is disclosed and comprises TRISO particles disposed in a matrix material, the TRISO particles comprising burnable absorber TRISO particles and TRISO fuel particles. The burnable absorber TRISO particles comprise a non-fissile, neutron-absorbing kernel, a porous carbon buffer layer surrounding the non-fissile, neutron-absorbing kernel, a first pyrolytic carbon layer surrounding the porous carbon buffer layer, a silicon carbide layer surrounding the pyrolytic carbon layer, and a second pyrolytic carbon layer surrounding the silicon carbide layer. The TRISO fuel particles comprise a fissile fuel kernel, a porous carbon buffer layer surrounding the fissile fuel kernel, a first pyrolytic carbon layer surrounding the porous carbon buffer layer, a silicon carbide layer surrounding the first pyrolytic carbon layer, and a second pyrolytic carbon layer surrounding the silicon carbide layer.

A method of forming a burnable absorber TRISO particle is disclosed and comprises forming a kernel comprising a burnable absorber material, forming a porous carbon buffer layer surrounding the kernel, forming a first pyrolytic carbon layer surrounding the porous carbon buffer layer, forming a silicon carbide layer surrounding the first pyrolytic carbon layer, and forming a second pyrolytic carbon layer surrounding the silicon carbide layer.

### BRIEF DESCRIPTION OF THE DRAWINGS

FIG. 1 is a schematic of a BA TRISO particle, in accordance with embodiments of the disclosure;

FIG. 2 is a flow diagram of a process of forming BA TRISO particles, in accordance with embodiments of the disclosure;

FIGS. 3A-3D are schematics of fuel compacts containing the BA TRISO particles and TRISO particles, in accordance with embodiments of the disclosure;

FIG. 4 is a flow diagram of a process of forming the fuel compacts, in accordance with embodiments of the disclosure; and

FIGS. 5A and 5B are schematics of nuclear reactors containing the fuel compacts, in accordance with embodiments of the disclosure.

### DETAILED DESCRIPTION

As used herein, the singular forms following “a,” “an,” and “the” are intended to include the plural forms as well, unless the context clearly indicates otherwise.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.).

As used herein, the term “burnable absorber tristructural isotropic (TRISO) particle” means and includes a particle including multiple materials (e.g., layers) surrounding a burnable absorber material that is non-fissile and formulated to absorb neutrons.

As used herein, the term “tristructural isotropic fuel particles” means and includes a particle including multiple materials (e.g., layers) surrounding a fuel material that is fissile and releases energy and neutrons. The fissile fuel material may be uranium oxycarbide, uranium dioxide, uranium nitride, uranium carbide, or a combination thereof.

As used herein, the term “tristructural isotropic particles” or “TRISO particles” collectively refers to the burnable absorber TRISO particles and TRISO fuel particles.

According to embodiments described herein, a burnable absorber (BA) material may be present in an inner portion (e.g., a core) of a BA TRISO particle. The BA material is formulated to absorb neutrons. The BA material is substantially surrounded by one or more other materials, encapsulating the BA within the BA TRISO particle. Rather than including a fissile uranium oxycarbide (UCO) or other fissile fuel material, which is present in TRISO fuel particles, the BA TRISO particles according to embodiments of the disclosure contain a non-fissile, neutron-absorbing material as a kernel material (e.g., an inner kernel, a BA kernel material). Therefore, the BA TRISO particles differ from the TRISO fuel particles in the kernel material used. The materials surrounding the BA may provide one or more of mechanical strength, mechanical integrity, protective properties, barrier properties, bonding properties, or gas absorption properties to the BA TRISO particles.

The BA TRISO particles according to embodiments of the disclosure are used in a core of a nuclear reactor (e.g., a nuclear reactor core) to reduce power peaking and extend the operational fuel cycle. The BA encapsulated within the BA TRISO particles is formulated to absorb excess neutrons generated by the highly reactive fuel used in the nuclear reactor. The BA TRISO particles may be used in a fuel compact along with the TRISO fuel particles, with the TRISO particles (e.g., the BA TRISO particles and the TRISO fuel particles) distributed in a matrix material. The fuel compact may be used in the core of the nuclear reactor. During use and operation of the nuclear reactor, excess neutrons generated by the fuel of the TRISO fuel particles are absorbed by the BA TRISO particles. Incorporating the BA TRISO particles in the fuel compact does not substantially change interactions between the TRISO fuel particles and the matrix material, which have been characterized over many years by the Advanced Gas Reactor (AGR) Fuel Development and Qualification Program.

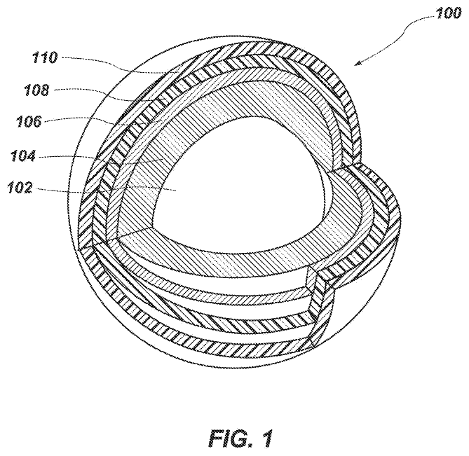

A BA TRISO particle 100 according to embodiments of the disclosure is shown in FIG. 1 and includes a BA kernel 102, a porous carbon buffer layer 104, an inner pyrolytic carbon (IPyC) layer 106, a silicon carbide (SiC) layer 108, and an outer pyrolytic carbon (OPyC) layer 110. The BA kernel 102 may be a non-fissile, BA material that exhibits a large neutron-absorption cross section. The BA kernel 102 is an innermost material of the BA TRISO particle 100 and may be configured as a core of the BA TRISO particle 100. The BA kernel 102 is substantially surrounded by the porous carbon buffer layer 104, which may absorb gas (e.g., helium) released by the BA kernel 102 upon absorption of neutrons. The porous carbon buffer layer 104 is substantially surrounded by the inner pyrolytic carbon (IPyC) layer 106, which may protect the BA kernel 102 from chloride interactions during the deposition of the SiC layer 108. The SiC layer 108 substantially surrounds the IPyC layer 106 and functions as a primary structural layer and pressure containment layer. The outer pyrolytic carbon (OPyC) layer 110 substantially surrounds the SiC layer 108, protecting the SiC during handling and providing a surface for bonding with the matrix material into which the BA TRISO particles are incorporated. The porous carbon buffer layer 104, the IPyC layer 106, the SiC layer 108, and the OPyC layer 110 may be configured as layers that substantially surround the BA kernel 102. For instance, the porous carbon buffer layer 104 may substantially surround the BA kernel 102, the IPyC layer 106 may substantially surround the porous carbon buffer layer 104, the SiC layer 108 may substantially surround the IPyC layer 106, and the OPyC layer 110 may substantially surround the SiC layer 108.

The BA TRISO particle 100 may be substantially spherical in shape and have a total diameter of from about 750 μm to about 1000 μm. However, the BA TRISO particles 100 may exhibit smaller diameters or larger diameters depending on the configuration of the nuclear reactor. The OPyC layer 110 may have a thickness of about 40 μm. The SiC layer 108 may have a thickness of about 35 μm. The IPyC layer 106 may have a thickness of about 40 μm. The porous carbon buffer layer 104 may have a thickness of about 100 μm, and may be fabricated with a porosity of about 53%. The BA kernel 102 may have a diameter of from about 350 μm to about 785 μm, such as from about 350 μm to about 500 μm or from about 535 μm to about 785 μm. However, the layers of the BA TRISO particles 100 may exhibit smaller thicknesses or larger thicknesses depending on the configuration of the nuclear reactor.

The burnable absorber material of the BA kernel 102 is a non-fissile, neutron-absorbing material that exhibits a neutron-absorption cross-section of from about 1.4 barns (10⁻²⁴ cm²) to about 253,000 barns at thermal neutron energies (0.025 electron-volts (eV)), and from about 0.04 barns to about 2.0 barns at fast neutron energies (200 keV, which is the flux peak for a sodium-cooled fast reactor). The neutron-absorbing material may be parasitic (e.g., sacrificial) during use and operation of the nuclear reactor in that the neutron-absorbing material is consumed at a rate proportional to the rate of fuel consumption such that the reactivity change by depletion of the burnable absorber is offset by depletion of the fuel and generation of fission products. The BA kernel 102 may be formed of and include boron carbide, as boron carbide is relatively cheap, abundant, and has excellent neutron-absorbing properties. The BA kernel 102 may, alternatively, be formed of and include boron carbide and another neutron-absorbing material, such as gadolinium oxide. Alternatively, the BA kernel 102 may be formed of and include a rare earth oxide material, a transition metal oxide material, a post-transition metal oxide material, a combination thereof, or a combination with boron carbide. The rare earth oxide may include, but is not limited to, gadolinium oxide, erbium oxide, europium oxide, dysprosium oxide, samarium oxide, lutetium oxide, or a combination thereof. The transition metal oxide may include, but is not limited to, hafnium oxide, cadmium oxide, iridium oxide, or a combination thereof. The post-transition metal oxide may include, but is not limited to, indium oxide. For instance, the BA kernel 102 may include 70% gadolinia and 30% erbium, or may include 60% gadolinia and 40% boron carbide. The BA kernel 102 may be used in its natural isotopic form or may include an enriched isotope of interest. For instance, if boron carbide is used, the BA kernel 102 may include B-10 in its natural abundance (about 20%) or may be enriched in B-10. Similarly, if gadolinium oxide is used, the BA kernel 102 may include Gd-157 in its natural abundance (about 15.7%) or may be enriched in Gd-157, such as having about 70% Gd-157.

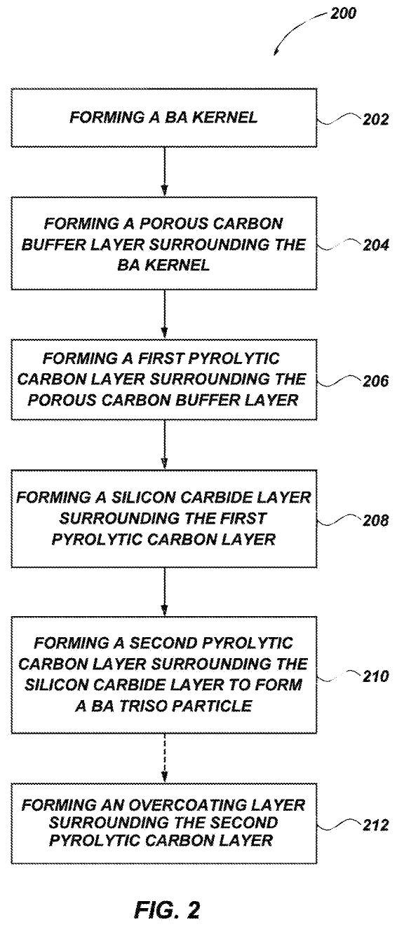

FIG. 2 is a flow diagram showing a process 200 according to embodiments of the disclosure for forming the BA TRISO particle 100. The process 200 includes act 202 of forming a BA kernel 102; act 204 of forming a porous carbon buffer layer 104 surrounding the BA kernel 102; act 206 of forming a first inner pyrolytic carbon (IPyC) layer 106 surrounding the porous carbon buffer layer 104; act 208 of forming a silicon carbide (SiC) layer 108 surrounding the first inner pyrolytic carbon (IPyC) layer 106; act 210 of forming a second outer pyrolytic carbon (OPyC) layer 110 surrounding the silicon carbide (SiC) layer 108; and optional act 212 of forming an overcoating layer surrounding the second pyrolytic carbon layer to form a BA TRISO particle 100.

The BA TRISO particles 100 may be formed using a similar (e.g., substantially the same) process used to form TRISO fuel particles, except that a BA kernel 102 is used rather than a UCO or other fissile fuel kernel. The neutron-absorbing material of the BA kernel 102 or a precursor compound of the neutron-absorbing material may be commercially available from numerous sources. The BA kernel 102 may be formed by, for example, a sol-gel process or a rotating electrode process. To form a BA kernel 102 using the sol-gel process, the precursor compound of the neutron-absorbing material may be dissolved in a solvent to initiate a sol. This dissolution of the precursor compound may involve controlled hydrolysis and polymerization reactions, resulting in the formation of a colloid with particles of the precursor compound dispersed uniformly throughout the solvent. The sol may then transition into a gel through careful adjustment of parameters such as concentration of the precursor compound in the solvent, temperature, and pH, creating a three-dimensional network of polymeric chains of the precursor compound that holds the solvent. The gel may undergo aging to improve its structural properties, followed by a drying process to extract the solvent, thus yielding a porous, solid matrix. Finally, the dried gel may be calcined at appropriate temperatures to eliminate any organic remnants and to facilitate sintering, producing a dense BA kernel 102 that is homogeneous in composition with a high degree of sphericity and purity.

To form a BA kernel 102 utilizing the rotating electrode process, a rod composed of the desired BA material may be formed by processing the desired BA material into a fine powder, compacting the powder, and then sintering the compacted powder at high temperatures to fuse the powder particles together into a dense, coherent mass. It may be subsequently machined to precise dimensions. The rod may be positioned within a vacuum or controlled atmosphere chamber and may then be rotated at a high velocity, such as above 10,000 revolutions per minute. This rotation leverages centrifugal forces, which are instrumental in the process. An electrical arc or discharge may be directed onto the surface of the rotating rod, inducing the localized melting and potential vaporizing of the BA material. Due to the centrifugal force exerted, the molten or partially vaporized BA material may then be ejected from the rod. As these particles move away from the rod and into cooler surroundings of the chamber, the particles may rapidly cool and solidify, forming spherical BA kernels 102. The rotating electrode process may enable fine-tuning of the BA kernel 102's size and uniformity by adjusting parameters such as the rotation speed of the rod, the intensity of the electrical discharge, and the composition of the chamber's atmosphere. This method may produce the BA kernels 102 with a high degree of sphericity and purity.

The additional layers of materials of the BA TRISO particles 100 may be sequentially deposited on the BA kernel 102 using different techniques tailored to each layer's properties, such as a fluidized bed chemical vapor deposition (CVD) process. In the fluidized bed CVD process, the BA kernel 102 may be introduced into a fluid-bed coater, into which ethyne and propene, as reactive gases, and argon, as a fluidization gas, may be injected, and pyrolyzed at a temperature of from about 1300° C. to about 1500° C. to deposit the porous carbon buffer layer 104 and IPyC layer 106 on the BA kernel 102. The fluid-bed coater may be a conventional fluid-bed coater. The SiC layer 108 may subsequently be deposited in the fluid-bed coater over the IPyC layer 106 using methyltrichlorosilane (MTS) vapor as the reactive gas, which may be entrained by hydrogen and pyrolyzed at about 1600° C. The OPyC layer 110 may subsequently be formed in the fluid-bed coater over the SiC layer 108 by injecting ethyne, propene and argon gases and pyrolyzing at a temperature of from about 1300° C. to about 1500° C. However, the materials of the BA TRISO particles 100 may be formed over the BA kernel 102 by other techniques. The BA TRISO particles 100 may then be sorted by size and shape to remove under-and over-sized particles. An overcoating layer may, optionally, be applied to the BA TRISO particles 100. For example, a graphitic matrix material may be applied to the exterior of the BA TRISO particles 100 to form an overcoating layer. The BA TRISO particles may then be characterized using a two-modulator generalized ellipsometer (2-MGE) optical technique used to characterize TRISO fuel particles. The particles may be characterized for desirable properties such as size and sphericity, layer thickness and uniformity, density and porosity, and chemical purity and composition. Additional acts may be conducted, as described below, to form fuel compacts containing the BA TRISO particles 100.

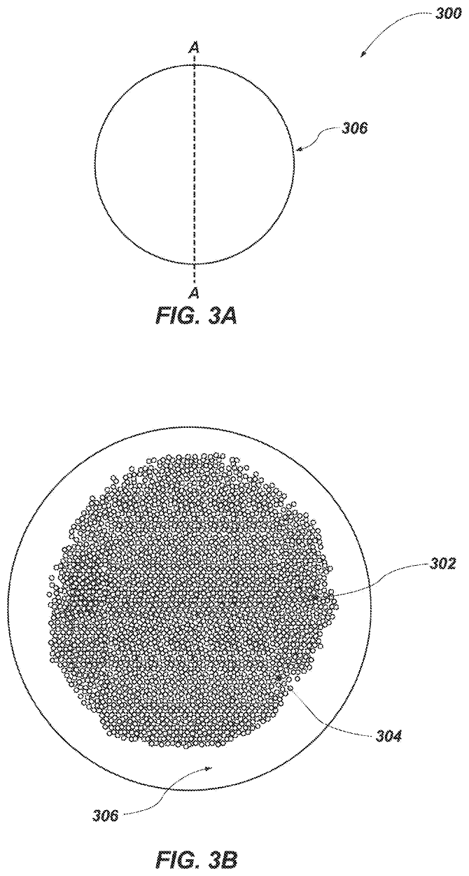

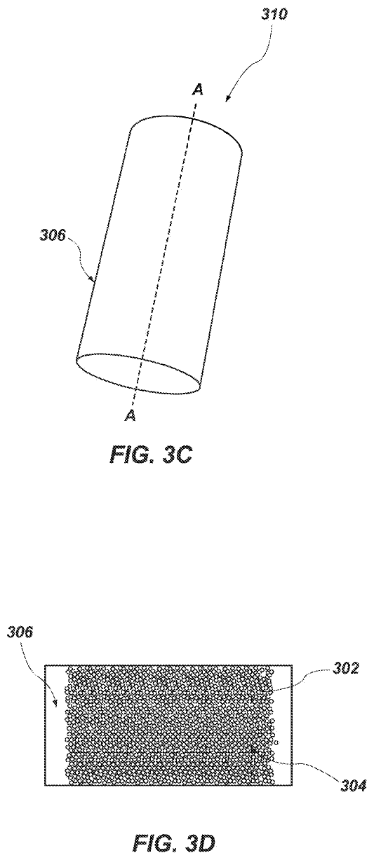

Fuel compacts 300 and 310 containing BA TRISO particles 302, according to embodiments of the disclosure, and TRISO fuel particles 304 are depicted in FIGS. 3A-3D. FIG. 3A is a simplified view of a spherical fuel compact 300. FIG. 3B is a simplified cross-sectional view of the spherical fuel compact 300 along the line A-A shown in FIG. 3A. FIG. 3C is a simplified view of a cylindrical fuel compact 310. FIG. 3D is a simplified cross-sectional view of the cylindrical fuel compact 310 along the line A-A shown in FIG. 3C. The BA TRISO particles 302 may be distributed (e.g., embedded) in a matrix material 306 (e.g., a carbon matrix, a graphite matrix) along with the TRISO fuel particles 304 to form a spherical fuel compact 300, as shown in FIG. 3A, or a cylindrical fuel compact 310, as shown in FIG. 3D. The TRISO fuel particles 304 may, for example, be UCO TRISO particles. Other shapes may be contemplated for the fuel compacts 300 and 310 depending on the configuration of the nuclear reactor. The spherical fuel compact 300 may have a diameter of about 60 mm, and the cylindrical fuel compact 310 may have a length of about 25.1 mm and a diameter of about 12.4 mm. However, the fuel compacts 300 and 310 may exhibit other dimensions, such as greater dimensions or smaller dimensions, depending on the size of the nuclear reactor in which the fuel compacts 300 and 310 are to be used.

The fuel compacts 300 and 310 may include up to about 10% by mass of the total TRISO particles (BA TRISO particles 302 and TRISO fuel particles 304). The spherical fuel compact 300 may contain from about 9,000 TRISO particles to about 18,000 TRISO particles, of which from about 0.01% by mass to about 10% by mass may be the BA TRISO particles 302, with the remainder being the TRISO fuel particles 304. By way of example only, the BA TRISO particles 302 may account for from about 0.01% by mass to about 5% by mass, from about 0.01% by mass to about 4% by mass, from about 0.01% by mass to about 3% by mass, from about 0.01% by mass to about 2% by mass, from about 0.01% by mass to about 1% by mass, from about 5% by mass to about 10% by mass, from about 6% by mass to about 10% by mass, from about 7% by mass to about 10% by mass, from about 8% by mass to about 10% by mass, or from about 9% by mass to about 10% by mass of the total TRISO particles (BA TRISO particles 302 and TRISO fuel particles 304).

The cylindrical fuel compact 310 may contain from about 1,500 TRISO particles to about 4,000 TRISO particles, of which from about 0.01% by mass to about 10% by mass may be the BA TRISO particles 302 and the remainder may be the TRISO fuel particles 304. By way of example only, the BA TRISO particles 302 may account for from about 0.01% by mass to about 5% by mass, from about 0.01% by mass to about 4% by mass, from about 0.01% by mass to about 3% by mass, from about 0.01% by mass to about 2% by mass, from about 0.01% by mass to about 1% by mass, from about 5% by mass to about 10% by mass, from about 6% by mass to about 10% by mass, from about 7% by mass to about 10% by mass, from about 8% by mass to about 10% by mass, or from about 9% by mass to about 10% by mass of the total TRISO particles (BA TRISO particles 302 and TRISO fuel particles 304).

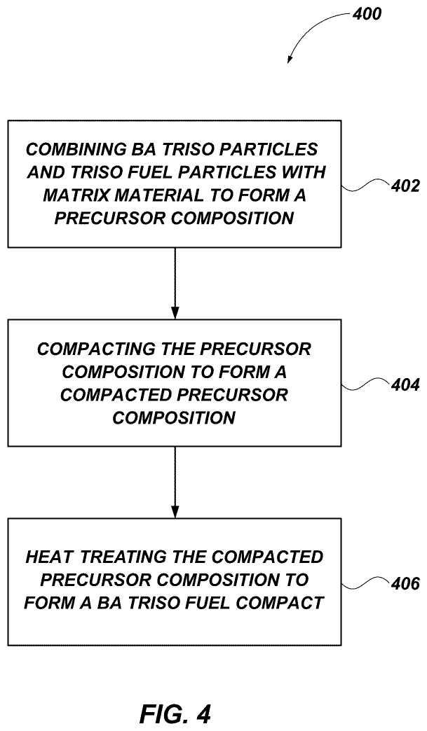

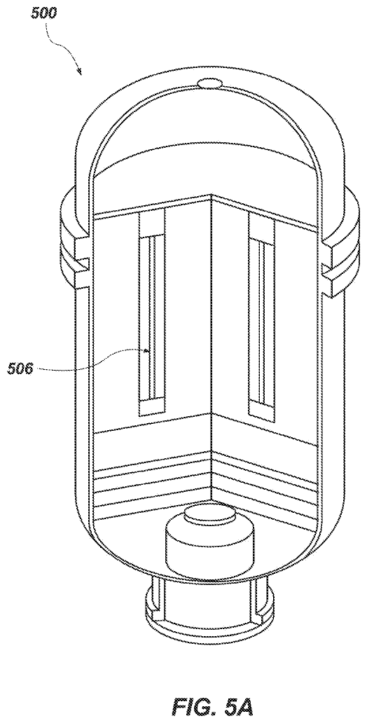

FIG. 4 is a flow diagram showing a process 400 according to embodiments of the disclosure for forming a fuel compact that includes the BA TRISO particles 302 and the TRISO fuel particles 304. The BA TRISO particles 302 may optionally include the overcoating previously described. The process 400 includes act 402 of combining BA TRISO particles 302 and TRISO fuel particles 304 with a matrix material 306 to form a precursor composition; act 404 of compacting the precursor composition to form a compacted precursor composition; and act 406 of heat treating the compacted precursor composition to form a BA TRISO fuel compact.

The acts of the process 400 may be performed using conventional techniques. The precursor composition may be formed by mechanically blending the BA TRISO particles 302 and TRISO fuel particles 304 with a matrix material 306, ensuring that the particles are evenly dispersed to prevent clustering and achieve mechanical stability in the final product. The compacted precursor composition may be formed by applying high pressure in a mold to consolidate the blended mixture, which enhances the contact between particles and matrix for improved structural integrity. A layer of matrix material 306 may, optionally, subsequently be formed around the periphery of the fuel compact. The layer of matrix material 306 may be substantially free of the BA TRISO particles 302 and the TRISO fuel particles 304. If, for example, the fuel compact is configured for use in a pebble reactor, the layer of the matrix material 306 may provide additional protection to reduce impacts to the TRISO particles 302, 304 and prevent the TRISO particles 302, 304 from falling out of the pebble. The heat treatment may include carbonizing the compacted mixture at a temperature range of about 800° C. to about 1800° C., which facilitates the formation of a solid graphite matrix around the particles, thereby locking them in place and enhancing the compact's overall durability and thermal stability. Since the layers of the BA TRISO particles 302 are substantially similar in chemical composition to layers of the TRISO fuel particles 304, the BA TRISO particles 302 may be easily incorporated into the matrix material 306 along with the TRISO fuel particles 304 in act 402. By way of example only, the BA TRISO particles 302 and the TRISO fuel particles 304 may be combined in a graphite matrix material 306, compacted, and carbonized at a temperature of from about 800° C. to about 1800° C. The resulting fuel compact contains the BA TRISO particles 302 and the TRISO fuel particles 304 in the graphite matrix material 306.

The BA TRISO particles 302 may be homogeneously distributed throughout the matrix material 306, as shown in FIGS. 3B and 3D, so that the fuel compacts 300 and 310 include a substantially uniform distribution of the BA TRISO particles 302. Alternatively, a gradient of the BA TRISO particles 302 may be present in the matrix material 306, with an inner portion (e.g., a center portion) of the fuel compacts 300 and 310 including a relatively greater concentration of the BA TRISO particles 302 than an outer portion of the fuel compacts 300 and 310.

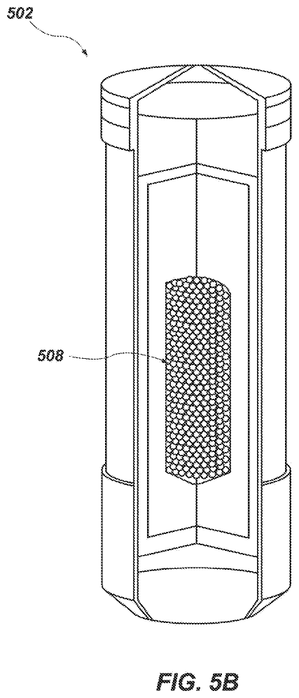

FIGS. 5A and 5B show prismatic graphite blocks 506 and spherical fuel compacts 508 according to embodiments of the disclosure in a nuclear reactor, such as an advanced nuclear reactor. The nuclear reactor may, for example, be a high-temperature gas-cooled reactor (HTGR), a prismatic reactor 500, a pebble bed reactor 502, or other advanced nuclear reactor. However, the BA TRISO particles 100 are not limited to use in HTGRs, and may also be used in other types of advanced nuclear reactors, such as microreactors or molten salt reactors. The fuel compacts 300 and 310 containing the BA TRISO particles 302 and the TRISO fuel particles 304 embedded in the matrix material 306 may be inserted into the nuclear reactor to control excess reactivity in the nuclear core and flatten the power profile. If the fuel compacts are configured as cylinders (e.g., cylindrical fuel compacts 310), the cylindrical fuel compacts 310 may be placed in prismatic graphite blocks 506 and inserted into a prismatic reactor 500 as depicted in FIG. 5A. Alternatively, if the fuel compacts are configured as spheres (e.g., spherical fuel compacts 300) spherical fuel compacts 508 may be inserted into a pebble bed reactor 502, as depicted in FIG. 5B. The fuel compacts 300 and 310 according to embodiments of the disclosure may be distributed homogenously throughout the core of the nuclear reactor. Alternatively, the fuel compacts 300 and 310 may be distributed so that relatively more fuel compacts containing the BA TRISO particles 100 may be placed near the center of the reactor core where more fission reactions occur and more heat is generated, while the periphery of the reactor core may contain relatively fewer fuel compacts containing the BA TRISO particles 100.

During operation of the nuclear reactor, the BA TRISO particles 100 may effectively contain fission products and control the rate of nuclear reactions, ensuring safe and efficient nuclear reactions. The BA material of the BA TRISO particles 100 may absorb neutrons, thereby mitigating excessive reactivity and extending the life of the fuel. As the BA abundance decreases, so does the BA's impact on reactivity. By including the BA material in the BA TRISO particles 100, a variety of safety and economic benefits, such as reactivity control and fuel cycle extension, may be achieved, which enables the nuclear reactor to produce more energy before being shut down for refueling. If the BA is consumed too quickly, then a positive reactivity swing later in the operational fuel cycle may exceed the allowable limits for the nuclear reactor. If the BA is consumed too slowly, then the remaining BA results in a negative reactivity penalty toward the end of the nuclear fuel's operational cycle. Therefore, the selection of BA type, quantity, and placement in the reactor core is important to using the fuel compacts according to embodiments of the disclosure. The fuel compacts according to embodiments of the disclosure also increase the lifetime of the control rods.

In contrast to the fuel compacts according to embodiments of the disclosure, conventional attempts to incorporate BAs into nuclear reactor cores include coating the TRISO fuel compacts with a BA material or incorporating the BA directly into a graphite matrix of the fuel compact. However, these methods have several disadvantages. The AGR Fuel Qualification Program has spent decades developing, fabricating, irradiating, characterizing, and qualifying TRISO fuel particles and the fuel compacts containing the TRISO fuel particles. Incorporating the BA directly into the graphite matrix would require a lengthy and expensive qualification effort in order to understand how the BA behaves and affects properties of the fuel compacts compared to those developed in the AGR program. Furthermore, boron carbide, a relatively cheap and abundant BA material with excellent neutronic properties, emits a helium nucleus when it absorbs a neutron. If boron carbide is incorporated directly into the graphite matrix of the fuel compacts, helium will accumulate and lead to an increased gas pressure. This accumulation of helium gas over time poses challenges when using boron carbide as a BA in advanced nuclear reactors. Since graphite is brittle, has a low hardness, and lacks rigidity, the graphite matrix may crack over the course of the fuel's operational cycle due to the helium overpressurization. The boron carbide may also diffuse (e.g., thermally diffuse) through the fuel compacts if cracks in the graphite matrix occur during the fuel's operational cycle. Diffusion/migration of other burnable absorber species (i.e., rare earth metals, like gadolinium, europium, etc.) may result in BA agglomeration, which may negatively influence BA burnout rates due to self-shielding, or they may chemically degrade the external layers of TRISO fuel particles in close proximity. Coating the fuel compacts with the BA material is also problematic because the coatings are susceptible to delamination, scratching, and cracking in the nuclear reactor environment, BA distribution in the coatings is extremely heterogeneous, and, for neutronics reasons, having the BA as close to the uranium as possible is often desired. However, inserting control rods deeper into the reactor core causes the power distribution to become increasingly nonuniform and decreases the effective control rod lifetime.

By encapsulating the BA with the other material layers according to embodiments of the disclosure, the BA may be contained within the BA TRISO particles, substantially preventing diffusion of the BA into the surrounding materials and damage to the other material layers. In other words, the other layers of the BA TRISO particles may keep the BA stationary throughout the operational fuel cycle. The BA in the BA TRISO particles may also mitigate the risks associated with helium accumulation (e.g., helium overpressurization). The incorporation of the BA in the BA TRISO particles also reduces failure (e.g., cracking) of the fuel compact containing the BA TRISO particles. By including the BA in the BA TRISO particles, the fuel in the TRISO fuel particles is maintained separate from the BA. In addition, outer portions of the BA TRISO particles are similar in chemical composition to the TRISO fuel particles so interactions with the matrix material are not substantially affected. Since the BA TRISO particles are similar in chemical composition to the TRISO fuel particles and the BA TRISO particles do not affect properties of the TRISO fuel particles and the matrix material, the time and costs associated with qualifying the fuel compact may be reduced compared to conventional attempts to incorporate BAs into nuclear reactor cores.

Placing the BA at the core (e.g., inner portion) of the BA TRISO particles and incorporating the BA TRISO particles in fuel compacts that include TRISO fuel particles provides several advantages. If, for example, boron carbide is used as the BA material and the matrix material is graphite, any helium gas produced upon the absorption of neutrons may be absorbed by the porous carbon buffer layer and the SiC layer may act as a pressure vessel, preventing helium overpressurization and cracking from the release of helium gas into the graphite matrix. By incorporating the BA TRISO particles into the matrix material (e.g., graphite matrix) along with the TRISO fuel particles, the BA may be distributed more homogeneously and be in closer proximity to the uranium of the TRISO fuel particles than if the BA were coated on the surface of the fuel compact. The BA TRISO particles also keep the BA stationary throughout the fuel's operational cycle, whereas the BA may migrate if it were mixed directly into the graphite matrix. Finally, the BA TRISO particles do not alter the properties of the matrix material or of the TRISO fuel particles, which means the fuel compacts according to embodiments of the disclosure do not require an exhaustive qualification effort.

Non-limiting, example embodiments may include the following, alone or in combination:

Embodiment 1: A burnable absorber tristructural isotropic (TRISO) particle comprising a kernel comprising a non-fissile, neutron-absorbing material; a porous carbon buffer layer surrounding the kernel; a first pyrolytic carbon layer surrounding the porous carbon buffer layer; a silicon carbide layer surrounding the first pyrolytic carbon layer; and a second pyrolytic carbon layer surrounding the silicon carbide layer.

Embodiment 2: The burnable absorber TRISO particle of Embodiment 1, wherein the non-fissile, neutron-absorbing material comprises boron carbide, gadolinium oxide, erbium oxide, hafnium oxide, europium oxide, dysprosium oxide, cadmium oxide, indium oxide, samarium oxide, lutetium oxide, iridium oxide, or a combination thereof.

Embodiment 3: The burnable absorber TRISO particle of Embodiments 1 and 2, wherein the non-fissile, neutron-absorbing material comprises an enriched isotope.

Embodiment 4: The burnable absorber TRISO particle of Embodiments 1 and 2, wherein the non-fissile, neutron-absorbing material is in a natural isotopic form.

Embodiment 5: The burnable absorber TRISO particle of Embodiments 1 through 4, wherein the burnable absorber TRISO particle is substantially spherical in shape and exhibits a diameter of from about 750 μm to about 1000 μm.

Embodiment 6: The burnable absorber TRISO particle of Embodiments 1 through 5, wherein the non-fissile, neutron-absorbing material has a diameter of from about 350 μm to about 785 μm, the first pyrolytic carbon layer has a thickness of about 40 μm, the silicon carbide layer has a thickness of about 35 μm, the second pyrolytic carbon layer has a thickness of about 40 μm, and the porous carbon buffer layer has a thickness of about 100 μm.

Embodiment 7: The burnable absorber TRISO particle of Embodiments 1 through 6, further comprising an overcoating layer surrounding the second pyrolytic carbon layer.

Embodiment 8: A fuel compact comprising tristructural isotropic (TRISO) particles disposed in a matrix material, the TRISO particles comprising burnable absorber TRISO particles and TRISO fuel particles, the burnable absorber TRISO particles comprising a non-fissile, neutron-absorbing kernel; a porous carbon buffer layer surrounding the non-fissile, neutron-absorbing kernel; a first pyrolytic carbon layer surrounding the porous carbon buffer layer; a silicon carbide layer surrounding the pyrolytic carbon layer; and a second pyrolytic carbon layer surrounding the silicon carbide layer; and the TRISO fuel particles comprising a fissile fuel kernel; a porous carbon buffer layer surrounding the fissile fuel kernel; a first pyrolytic carbon layer surrounding the porous carbon buffer layer; a silicon carbide layer surrounding the first pyrolytic carbon layer; and a second pyrolytic carbon layer surrounding the silicon carbide layer.

Embodiment 9: The fuel compact of Embodiment 8, wherein the burnable absorber TRISO particles comprise from about 0.01% by mass to about 10% by mass of the TRISO particles and the TRISO fuel particles comprise from about 90% by mass to about 99.99% by mass of the TRISO particles.

Embodiment 10: The fuel compact of Embodiments 8 and 9, wherein the non-fissile, neutron-absorbing kernel comprises boron carbide, gadolinium oxide, erbium oxide, hafnium oxide, europium oxide, dysprosium oxide, cadmium oxide, indium oxide, samarium oxide, lutetium oxide, iridium oxide, or a combination thereof.

Embodiment 11: The fuel compact of Embodiments 8 through 10, wherein the burnable absorber TRISO particles are homogeneously distributed throughout the fuel compact.

Embodiment 12: The fuel compact of Embodiments 8 through 10, wherein the burnable absorber TRISO particles are heterogeneously distributed throughout the fuel compact.

Embodiment 13: The fuel compact of Embodiments 8 through 12, wherein the fissile fuel kernel comprises uranium oxycarbide, uranium dioxide, uranium nitride, uranium carbide, or a combination thereof.

Embodiment 14: The fuel compact of Embodiments 8 through 13, wherein the fuel compact is substantially spherical in shape or substantially cylindrical in shape.

Embodiment 15: A method of forming a burnable absorber tristructural isotropic particle, the method comprising forming a kernel comprising a burnable absorber material; forming a porous carbon buffer layer surrounding the kernel; forming a first pyrolytic carbon layer surrounding the porous carbon buffer layer; forming a silicon carbide layer surrounding the first pyrolytic carbon layer; and forming a second pyrolytic carbon layer surrounding the silicon carbide layer.

Embodiment 16: The method of Embodiment 15, wherein forming the kernel comprises forming the kernel comprising boron carbide, gadolinium oxide, erbium oxide, hafnium oxide, europium oxide, dysprosium oxide, cadmium oxide, indium oxide, samarium oxide, lutetium oxide, or iridium oxide.

Embodiment 17: The method of Embodiments 15 and 16, wherein forming the kernel comprises forming the kernel by a sol-gel process or a rotating electrode process.

Embodiment 18: The method of Embodiments 15 through 17, further comprising forming an overcoating layer surrounding the second pyrolytic carbon layer.

Embodiment 19: The method of Embodiments 15 through 18, wherein forming a burnable absorber tristructural isotropic particle comprises forming the burnable absorber tristructural isotropic particle to be substantially spherical in shape and have a diameter of from about 750 μm to about 1000 μm.

Embodiment 20: The method of Embodiments 15 through 19, wherein: forming the kernel comprises forming a non-fissile neutron-absorbing kernel exhibiting a diameter of from about 350 μm to about 785 μm; forming the porous carbon buffer layer surrounding the kernel comprises forming the porous carbon buffer layer exhibiting a thickness of about 100 μm; forming the first pyrolytic carbon layer surrounding the porous carbon buffer layer comprises forming the first pyrolytic carbon layer exhibiting a thickness of about 40 μm; forming the silicon carbide layer surrounding the first pyrolytic carbon layer comprises forming the silicon carbide layer exhibiting a thickness of about 35 μm; and forming the second pyrolytic carbon layer surrounding the silicon carbide layer comprises forming the second pyrolytic carbon layer exhibiting a thickness of about 40 μm.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

1. A burnable absorber tristructural isotropic (TRISO) particle comprising:
a kernel comprising a non-fissile, neutron-absorbing material;
a porous carbon buffer layer surrounding the kernel;
a first pyrolytic carbon layer surrounding the porous carbon buffer layer;
a silicon carbide layer surrounding the first pyrolytic carbon layer; and
a second pyrolytic carbon layer surrounding the silicon carbide layer.

2. The burnable absorber TRISO particle of claim 1, wherein the non-fissile, neutron-absorbing material comprises boron carbide, gadolinium oxide, erbium oxide, hafnium oxide, europium oxide, dysprosium oxide, cadmium oxide, indium oxide, samarium oxide, lutetium oxide, iridium oxide, or a combination thereof.

3. The burnable absorber TRISO particle of claim 2, wherein the non-fissile, neutron-absorbing material comprises an enriched isotope.

4. The burnable absorber TRISO particle of claim 2, wherein the non-fissile, neutron-absorbing material is in a natural isotopic form.

5. The burnable absorber TRISO particle of claim 1, wherein the burnable absorber TRISO particle is substantially spherical in shape and exhibits a diameter of from about 750 μm to about 1000 μm.

6. The burnable absorber TRISO particle of claim 1, wherein the non-fissile, neutron-absorbing material has a diameter of from about 350 μm to about 785 μm, the first pyrolytic carbon layer has a thickness of about 40 μm, the silicon carbide layer has a thickness of about 35 μm, the second pyrolytic carbon layer has a thickness of about 40 μm, and the porous carbon buffer layer has a thickness of about 100 μm.

7. The burnable absorber TRISO particle of claim 1, further comprising an overcoating layer surrounding the second pyrolytic carbon layer.

8. A fuel compact comprising:
tristructural isotropic (TRISO) particles disposed in a matrix material, the TRISO particles comprising burnable absorber TRISO particles and TRISO fuel particles, the burnable absorber TRISO particles comprising:
a non-fissile, neutron-absorbing kernel;
a porous carbon buffer layer surrounding the non-fissile, neutron-absorbing kernel;
a first pyrolytic carbon layer surrounding the porous carbon buffer layer;
a silicon carbide layer surrounding the pyrolytic carbon layer; and
a second pyrolytic carbon layer surrounding the silicon carbide layer; and
the TRISO fuel particles comprising:
a fissile fuel kernel;
a porous carbon buffer layer surrounding the fissile fuel kernel;
a first pyrolytic carbon layer surrounding the porous carbon buffer layer;
a silicon carbide layer surrounding the first pyrolytic carbon layer; and
a second pyrolytic carbon layer surrounding the silicon carbide layer.

9. The fuel compact of claim 8, wherein the burnable absorber TRISO particles comprise from about 0.01% by mass to about 10% by mass of the TRISO particles and the TRISO fuel particles comprise from about 90% by mass to about 99.99% by mass of the TRISO particles.

10. The fuel compact of claim 8, wherein the non-fissile, neutron-absorbing kernel comprises boron carbide, gadolinium oxide, erbium oxide, hafnium oxide, europium oxide, dysprosium oxide, cadmium oxide, indium oxide, samarium oxide, lutetium oxide, iridium oxide, or a combination thereof.

11. The fuel compact of claim 8, wherein the burnable absorber TRISO particles are homogeneously distributed throughout the fuel compact.

12. The fuel compact of claim 8, wherein the burnable absorber TRISO particles are heterogeneously distributed throughout the fuel compact.

13. The fuel compact of claim 8, wherein the fissile fuel kernel comprises uranium oxycarbide, uranium dioxide, uranium nitride, uranium carbide, or a combination thereof.

14. The fuel compact of claim 8, wherein the fuel compact is substantially spherical in shape or substantially cylindrical in shape.

15. A method of forming a burnable absorber tristructural isotropic particle, the method comprising:
forming a kernel comprising a burnable absorber material;
forming a porous carbon buffer layer surrounding the kernel;
forming a first pyrolytic carbon layer surrounding the porous carbon buffer layer;
forming a silicon carbide layer surrounding the first pyrolytic carbon layer; and
forming a second pyrolytic carbon layer surrounding the silicon carbide layer.

16. The method of claim 15, wherein forming the kernel comprises forming the kernel comprising boron carbide, gadolinium oxide, erbium oxide, hafnium oxide, europium oxide, dysprosium oxide, cadmium oxide, indium oxide, samarium oxide, lutetium oxide, or iridium oxide.

17. The method of claim 15, wherein forming the kernel comprises forming the kernel by a sol-gel process or a rotating electrode process.

18. The method of claim 15, further comprising forming an overcoating layer surrounding the second pyrolytic carbon layer.

19. The method of claim 15, wherein forming a burnable absorber tristructural isotropic particle comprises forming the burnable absorber tristructural isotropic particle to be substantially spherical in shape and have a diameter of from about 750 μm to about 1000 μm.

20. The method of claim 15, wherein:
forming the kernel comprises forming a non-fissile neutron-absorbing kernel exhibiting a diameter of from about 350 μm to about 785 μm;
forming the porous carbon buffer layer surrounding the kernel comprises forming the porous carbon buffer layer exhibiting a thickness of about 100 μm;
forming the first pyrolytic carbon layer surrounding the porous carbon buffer layer comprises forming the first pyrolytic carbon layer exhibiting a thickness of about 40 μm;
forming the silicon carbide layer surrounding the first pyrolytic carbon layer comprises forming the silicon carbide layer exhibiting a thickness of about 35 μm, and
forming the second pyrolytic carbon layer surrounding the silicon carbide layer comprises forming the second pyrolytic carbon layer exhibiting a thickness of about 40 μm.
